(19) United States
(12) Patent Application Publication
(10) Pub. No.: US 2026/0105226 A1
(43) Pub. Date: Apr. 16, 2026

(54) CLOCK GATING CLONING IN DESIGN FOR TEST PRACTICE

(71) Applicant: QUALCOMM Incorporated, San Diego, CA (US)

(72) Inventors: Paul POLICKE, Cedar Park, TX (US); Shwetha SHIVASHANKAR MURTHY, Pflugerville, TX (US)

(21) Appl. No.: 18/917,915

(22) Filed: Oct. 16, 2024

(51) Int. Cl. G01R 31/317

(52) U.S. Cl. CPC G06F 30/30; G01R 31/31704; G01R 31/31727

(57) ABSTRACT

A method of managing a clock signal in a design for test process for testing one or more processing cores includes applying a clock signal to a circuit to test one or more cores in accordance with a design for test process. The circuit includes at least a first clock gate path and a second clock gate path. One or more clock gates is controlled to disable at least one of the first clock gate path of the circuit or the second clock gate path based on a test mode of the design for test process.

### BACKGROUND

### Field

Aspects of the present disclosure relate to computing devices, and more specifically to clock gating cloning in design for test practice.

### Background

Mobile or portable computing devices include mobile phones, laptop, palmtop and tablet computers, portable digital assistants (PDAs), portable game consoles, and other portable electronic devices. Mobile computing devices are comprised of many electrical components that consume power and generate heat. The components (or compute devices) may include system-on-a-chip (SoC) devices, graphics processing unit (GPU) devices, neural processing unit (NPU) devices, digital signal processors (DSPs), and modems, among others.

The compute devices may increasingly use cores that include pre-designed and pre-verified design modules. The cores are tested prior to assembly in wireless devices to ensure that the chip functions as desired within specified operating parameters. Testing the cores may rely on a design for test (DFT) practice that incorporates rules and techniques for testing into the design of the chip to facilitate testing prior to delivery. DFT may be used to manage test complexity, minimize development time, and reduce manufacturing costs.

In DFT, various functions of the cores may be tested to validate the design. The DFT practice may include an Intest mode and an Extest mode. In the Intest mode, the internal logic of a core may be tested in isolation of the surrounding logic. In the Extest mode, the interface logic of the isolated core may be tested. As devices become more complex with more functions provided within one chip, additional clocks are used to synchronize and control functions performed by the multiple cores within the device. In complex hierarchical designs, a parent core may have multiple child cores, which are also tested. It is challenging to isolate the parent core from clocking activity of other cores, which may result in reduced efficacy in test validation as well as increased power consumption.

### SUMMARY

The present disclosure is set forth in the independent claims, respectively. Some aspects of the disclosure are described in the dependent claims.

In various aspects of the present disclosure, a method for managing a clock signal in a design for test process for testing one or more processing cores includes applying a clock signal to a circuit to test one or more cores in accordance with a design for test process. The method also includes controlling one or more clock gates to disable at least one of the first clock gate path of the circuit or the second clock gate path based on a test mode of the design for test process.

Various aspects of the present disclosure are directed to an apparatus for managing a clock signal in a design for test process for testing one or more processing cores. The apparatus includes a first clock gate coupled to one or more internal registers on a first clock gate path. The apparatus also includes at least one clone of the first clock gate coupled to at least one wrapper chain on a second clock gate path. The apparatus further includes a first user-defined clock gate coupled to the first clock gate. The first user-defined clock gate is configured to gate a clock signal to the one or more internal registers based on a mode of the design for test process.

In various aspects of the present disclosure, an apparatus for managing a clock signal in a design for test process for testing one or more processing cores is provided. The apparatus includes means for applying a clock signal to a circuit to test one or more cores in accordance with a design for test process. The circuit includes at least a first clock gate path and a second clock gate path. The apparatus also includes means for controlling one or more clock gates to disable at least one of the first clock gate path of the circuit or the second clock gate path based on a test mode of the design for test process.

This has outlined, rather broadly, the features and technical advantages of the present disclosure in order that the detailed description that follows may be better understood. Additional features and advantages of the present disclosure will be described below. It should be appreciated by those skilled in the art that this present disclosure may be readily utilized as a basis for modifying or designing other structures for carrying out the same purposes of the present disclosure. It should also be realized by those skilled in the art that such equivalent constructions do not depart from the teachings of the present disclosure as set forth in the appended claims. The novel features, which are believed to be characteristic of the present disclosure, both as to its organization and method of operation, together with further objects and advantages, will be better understood from the following description when considered in connection with the accompanying figures. It is to be expressly understood, however, that each of the figures is provided for the purpose of illustration and description only and is not intended as a definition of the limits of the present disclosure.

### BRIEF DESCRIPTION OF THE DRAWINGS

For a more complete understanding of the present disclosure, reference is now made to the following description taken in conjunction with the accompanying drawings.

FIG. 1 illustrates an example implementation of a host system-on-a-chip (SoC), including a mixed signal waveform-aware measurement system, in accordance with certain aspects of the present disclosure.

FIG. 2 is a block diagram illustrating an example computing system, in accordance with various aspects of the present disclosure.

FIG. 3 is a block diagram illustrating example circuitry for clock gating, in accordance with various aspects of the present disclosure.

FIG. 4 is a flow diagram illustrating an example process performed, for example, by a processor that is managing a clock in a design for test process, in accordance with various aspects of the present disclosure.

### DETAILED DESCRIPTION

The detailed description set forth below, in connection with the appended drawings, is intended as a description of various configurations and is not intended to represent the only configurations in which the concepts described may be practiced. The detailed description includes specific details for the purpose of providing a thorough understanding of the various concepts. It will be apparent, however, to those skilled in the art that these concepts may be practiced without these specific details. In some instances, well-known structures and components are shown in block diagram form in order to avoid obscuring such concepts.

As described, the use of the term “and/or” is intended to represent an “inclusive OR,” and the use of the term “or” is intended to represent an “exclusive OR.” As described, the term “exemplary” used throughout this description means “serving as an example, instance, or illustration,” and should not necessarily be construed as preferred or advantageous over other exemplary configurations. As described, the term “coupled” used throughout this description means “connected, whether directly or indirectly through intervening connections (e.g., a switch), electrical, mechanical, or otherwise,” and is not necessarily limited to physical connections. Additionally, the connections can be such that the objects are permanently connected or releasably connected. The connections can be through switches. As described, the term “proximate” used throughout this description means “adjacent, very near, next to, or close to.” As described, the term “on” used throughout this description means “directly on” in some configurations, and “indirectly on” in other configurations.

Processing core design may involve a design for test practice. The design for test (DFT) practice may be used to test the processors for defects and faults. The DFT practice may employ a wrapper around a target core. The wrapper may isolate a boundary between the target core and external logic to enhance the observability of the core and to control the inputs and outputs of the core.

The DFT practice may include an Intest mode and an Extest mode. In the Intest mode, the internal logic of a core may be tested in isolation of the surrounding logic. In the Intest mode, test data may be shifted into the input core scan wrapper cells and applied to the internal logic of the core. The responses of the internal logic are captured into the output core scan wrapper cells and shifted out for analysis.

On the other hand, in the Extest mode, the interface logic of the isolated core may be evaluated. That is, in Extest mode, interconnections between different cores of a System-on-a-Chip (SoC) may be evaluated. In the Extest mode, test data may be captured in the input scan wrapper cells and the output scan wrapper cells may provide stimulus. The core scan wrapper chains may shift out for data comparison. The Extest mode consists of wrapper chains, which can be shared and dedicated wrapper registers. Shared wrapper chains may comprise re-use of functional sequential elements or registers. Because conventional approaches include the clock to the wrapper registers on a common path with the internal scan registers, there may be unnecessary switching on internal scan registers.

The responses from the external pins may be captured back into the boundary scan cells and then shifted out for analysis. In both modes, conventional designs have all clocks toggling, which may result in excessive clock power switching activities.

In complex hierarchical design, a parent core may have multiple children (e.g., child cores). When the parent core is in Intest mode, it is desirable to have minimal clocking activity for the child cores in Extest mode.

Conventional core testing configurations use common clock gating configurations (CGCs) for internal and wrapper scan registers. In the Extest mode, while the internal registers are not used, the clock to the internal registers is active because the clock gate paths are shared. Thus, core testing using the conventional approach may result in excessive switching on the internal registers and increased power consumption.

Accordingly, aspects of the present disclosure are directed to cloning clock gate paths of shared wrapper registers. A non-cloned clock gate path may incorporate a clock gating cell that turns off the clock to internal scan registers when not utilized.

Particular aspects of the subject matter described in this disclosure can be implemented to realize one or more of the following potential advantages. In some examples, the described techniques may reduce the impact of excessive clock toggling during testing of cores in the Extest mode, may reduce dynamic power (e.g., switching power) in the Extest mode, and may improve test quality.

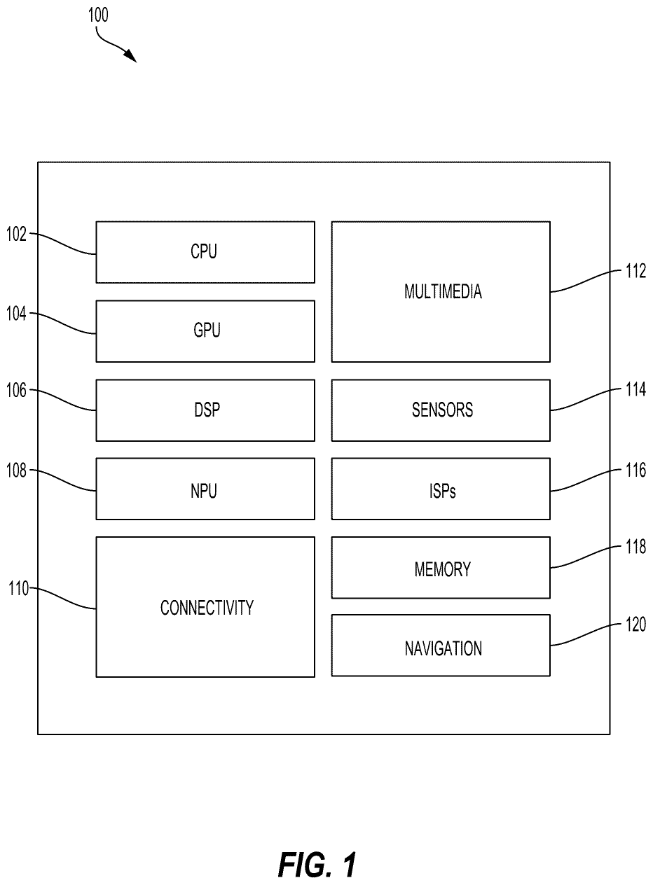

FIG. 1 illustrates an example implementation of a host system-on-a-chip (SoC) 100, which includes a mixed signal waveform-aware measurement system, in accordance with various aspects of the present disclosure. The host SoC 100 includes processing blocks tailored to specific functions, such as a connectivity block 110. The connectivity block 110 may include fifth generation (5G) connectivity, fourth generation long term evolution (4G LTE) connectivity, Wi-Fi connectivity, universal serial bus (USB) connectivity, Bluetooth® connectivity, Secure Digital (SD) connectivity, and the like.

In this configuration, the host SoC 100 includes various processing units that support multi-threaded operation. For the configuration shown in FIG. 1, the host SoC 100 includes a multi-core central processing unit (CPU) 102, a graphics processor unit (GPU) 104, a digital signal processor (DSP) 106, and a neural processor unit (NPU) 108. The host SoC 100 may also include a sensor processor 114, image signal processors (ISPs) 116, a navigation module 120, which may include a global positioning system (GPS), and a memory 118. The multi-core CPU 102, the GPU 104, the DSP 106, the NPU 108, and the multi-media engine 112 support various functions such as video, audio, graphics, gaming, artificial networks, and the like. Each processor core of the multi-core CPU 102 may be a reduced instruction set computing (RISC) machine, an advanced RISC machine (ARM), a microprocessor, or some other type of processor. The NPU 108 may be based on an ARM instruction set.

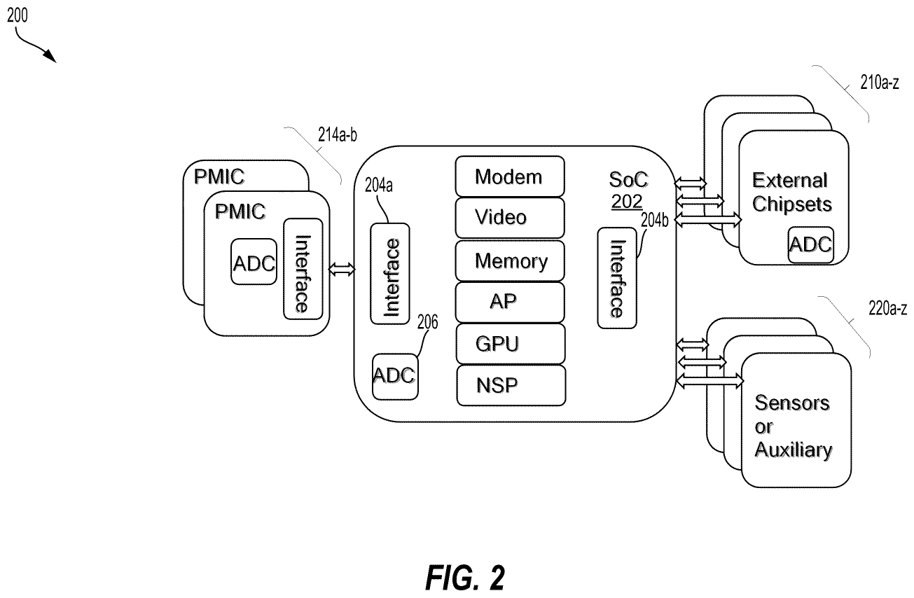

FIG. 2 is a block diagram illustrating an example computing system 200, in accordance with various aspects of the present disclosure. As shown in FIG. 2, the example computing system 200 includes a host SoC 202. The host SoC 202 may include components and function similar to the SoC 100 of FIG. 1. As shown in FIG. 2, the host SoC 202 includes interface circuitry 204a-b and an analog-to-digital converter (ADC) 206. The interface circuitry 204a-b may provide connectivity to one or more power management integrated circuits (PMICs) 214a-b. In addition, the interface circuitry may provide connectivity to one or more external chipsets 210a-z as well as external sensors or auxiliary integrated circuit (IC) devices 220a-z. In some aspects, the external chipsets 210a-z may, for example, include additional processors, such as one or more external GPUs or one or more wireless communication devices that may facilitate communication such as 5G, sixth generation (6G), vehicle-to everything communication (V2X), wireless local area network (WLAN), and the like. Moreover, in various aspects, the external chipsets 210a-z may, for example, relate to vehicle control and safety systems.

The sensors/auxiliary IC devices 220a-z may include power sensors (e.g., digital power meters), thermal sensors, current sensors, voltage sensors, and transmit power level sensors,

The SoC 202 includes the ADC 206. The ADC 206 may periodically sample and monitor mixed signals such as internal on-chip current sensor and voltage sensor outputs. Additionally, the ADC 206 may periodically sample and monitor off-chip parameters such as sensor output parameters associated with the sensors/auxiliary IC devices 220a-z. In an example, the ADC 206 may receive an analog voltage signal (e.g., through the interface circuitry 204a) from a power supply (e.g., PMIC 214a-b). The ADC 206 may digitally encode the analog signal to convert the analog voltage signal to a digital output. The ADC 206 may include both analog and digital circuits, and thus, may be considered a mixed-signal integrated circuit. In some aspects, the ADC 206 may also convert other analog signals supplied to the computing system 200 to a digital output. For instance, the ADC 206 may convert analog signals from sensors (e.g., 114 of FIG. 1 or sensors/auxiliary IC devices 220a-z) such as temperature sensors, light sensors, sonar signal, video signals, gyroscope sensors, and the like.

As described, aspects of the present disclosure are directed to cloning clock gate paths of shared wrapper registers. A non-cloned clock gate path may incorporate a clock gating cell that turns off the clock to internal scan registers when not utilized.

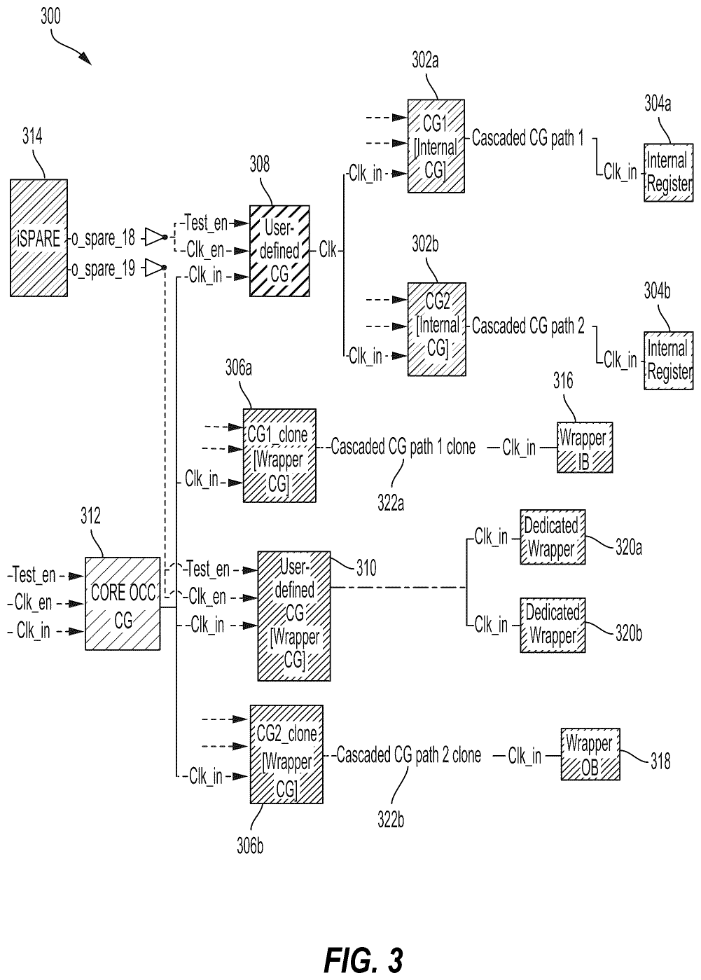

FIG. 3 is a block diagram illustrating example circuitry 300 for clock gating, in accordance with aspects of the present disclosure. The example circuitry 300 may implement a design for test practice for validating one or more cores such as the SoC 100 and/or included components (e.g., CPU 102 or NPU 108), for example. The example circuitry 300 includes a pair of internal clock gates CG1 302a and CG2 302b. The internal clock gates CG1 302a and CG2 302b are respectively coupled to internal registers 304a and 304b. The example circuitry 300 may also include a clone of each of the internal clock gates, CG1 clone 306a and CG2 clone 306b. The CG1 clone 306a and CG2 clone 306b may have the same inputs and clock (clk) signal as the internal clock gates CG1 302a and CG2 302b. In this way, a clock gating path to CG1 302a and CG2 302b may be cloned.

The example circuitry 300 may also include also include a user-defined clock gate (CG) 308, a user-defined CG wrapper 310, a core on-chip clock controller (OCC) 312, and a joint test action group (JTAG) controller 314 (shown as iSPARE).

The core OCC 312 supplies a clock signal to each of the CG1 clone 306a, CG2 clone 306b, the user-defined CG 308, and user-defined CG wrapper 310. The CG1 clone 306a is coupled via a cascaded CG path 322a to a clock input of a wrapper input boundary (IB) 316. The CG2 clone 306b is coupled via a cascaded CG path 322b to a clock input of a wrapper output boundary (OB) 318.

The JTAG controller 314 has a first output that is inverted and supplied to test enable and clock enable inputs of the user-defined CG 308. The user-defined CG 308 is coupled at an output to the CG1 302a and the CG2 302b, which are respectively coupled through cascaded CG paths to clock inputs of the internal registers 304a and 304b.

A second output of the JTAG controller 314 is inverted and supplied to a test enable input and a clock enable input of the user-defined CG wrapper 310. The user-defined CG wrapper 310 is coupled via a common clock input path to dedicated wrappers 320a, 320b.

Accordingly, in operation, the example circuitry 300 may be used to test one or more processor cores (e.g., of SoC 100) using design for test (DFT) practice, for instance. In the DFT practice implementation, the user-defined CG 308 and the user-defined CG wrapper 310 may serve to configure the example circuitry 300 to operate in the Intest mode. For instance, the JTAG controller 314 may activate the Intest mode. The JTAG controller 314 may provide a clock enable and test enable signal to the user-defined CG 308 and the user-defined CG wrapper 310. As such, when the core OCC 312 supplies a clock signal to the user-defined CG 308, the user-defined CG 308 may supply the clock signal to the CG1 302a and 302b which may in turn supply the clock signal along the respective cascaded CG path (cascaded CG path 1 and cascaded CG path 2) to the internal registers 304a and 304b.

Similarly, when the core OCC 312 supplies a clock signal to the user-defined CG wrapper 310, the user-defined CG wrapper 310 may supply the clock signal to the dedicated wrappers 320a and 320b.

In the Intest mode, wrapper IB 316 (e.g., input wrappers) may provide stimulus data to the core being tested (e.g., SoC 100) and the internal registers(e.g., 304a, 304b). The output wrappers (OB) (e.g., 318) may capture/observe responses from the core and the internal registers. Accordingly, the internal logic of the core may be tested.

On the other hand, the user-defined CG 308 and the user-defined CG wrapper 310 may also serve to configure the example circuitry 300 to operate in the Extest mode. For example, the JTAG controller 314 may activate the Extest mode. The JTAG controller 314 may provide a clock enable and test enable signal to the user-defined CG wrapper 310. However, the user-defined CG 308 may withhold the clock signal from the CG1 302a CG2 302b and the internal registers 304a, 304b, which may not be used in the Extest mode.

When the core OCC 312 supplies a clock signal to the user-defined CG wrapper 310, the user-defined CG wrapper 310 may supply the clock signal to the dedicated wrappers 320a and 320b. However, when the core OCC 312 supplies a clock signal to the user-defined CG 308, the clock signal is not provided to the CG1 302a, CG2 302b or the internal registers. As such, the user-defined CG 308 and user-defined CG wrapper may serve to isolate the circuitry involved in Extest mode.

In the Extest mode, the output wrapper registers (e.g., dedicated wrappers 320a, 320b) may provide stimulus data out of the core. The input scan wrapper registers (IB) (e.g., 316) may capture responses from ports/input functional logic. In this way, the interconnections (e.g., ports) between cores (e.g., cores of SoC 100) may be tested.

Although the present disclosure has described applying the example circuitry 300 to conduct test to detect defects between the one or more processing cores and interconnections between cores, the present disclosure is not so limiting. Rather, the example circuitry 300 may also be applied to test for defects between integrated circuits (ICs) on a printed circuit board. For example, the scan wrapper cells (e.g., 316, 318) for one IC may be in Extest while another IC could be in Intest. The IC with scan wrapper cells in Extest may have no clock provided (and therefore no clock toggle) for the internal registers (e.g., 304a, 304b).

Accordingly, clock switching activity and power consumption, related to providing clock signal during the Extest mode to the internal registers 304a, 304b, which are not used in the Extest mode, may be reduced.

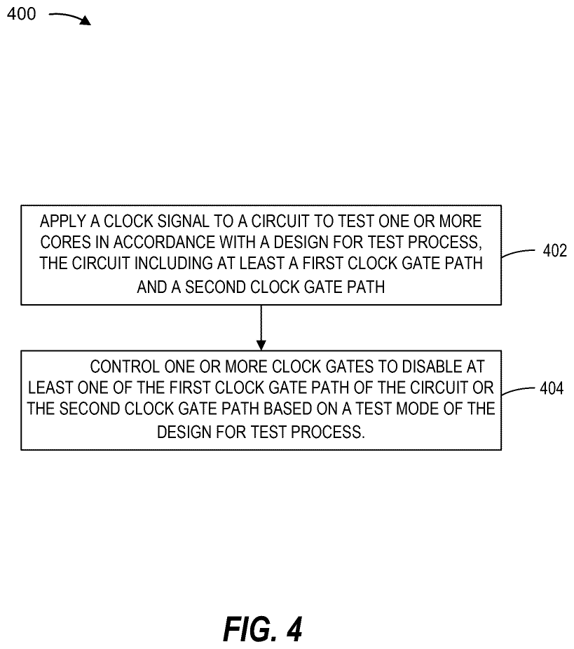

FIG. 4 is a flow diagram illustrating an example process 400 performed, for example, by a processor, in accordance with various aspects of the present disclosure.

At block 402 the processor applies a clock signal to a circuit to test one or more cores in accordance with a design for test process. The circuit includes at least a first clock gate path and a second clock gate path. For example, as described with reference to FIG. 4, in the DFT practice implementation, the user-defined CG 308 and the user-defined CG wrapper 310 may serve to configure the example circuitry 300 to operate in the Intest mode. The JTAG controller 314 may provide a clock enable and test enable signal to the user-defined CG 308 and the user-defined CG wrapper 310. As such, when the core OCC 312 supplies a clock signal to the user-defined CG 308, the user-defined CG 308 may supply the clock signal to the CG1 302a and 302b which may in turn supply the clock signal along the respective cascaded CG path (cascaded CG path 1 and cascaded CG path 2) to the internal registers 304a and 304b. In addition, when the core OCC 312 supplies a clock signal to the user-defined CG wrapper 310, the user-defined CG wrapper 310 may supply the clock signal to the dedicated wrappers 320a and 320b.

At block 404, the processor controls one or more clock gates to disable at least one of the first clock gate path of the circuit or the second clock gate path based on a test mode of the design for test process. In some aspects, the test mode may comprise an Intest mode or an Extest mode. For instance, as described with reference to FIG. 4, the user-defined CG 308 and the user-defined CG wrapper 310 may also serve to configure the example circuitry 300 to operate in the Extest mode. The JTAG controller 314 may provide a clock enable and test enable signal to the user-defined CG wrapper 310. However, the user-defined CG 308 may withhold the clock signal from the CG1 302a CG2 302b and the internal registers 304a, 304b, which may not be used in the Extest mode.

In some aspects, the one or more cores may be included in the same system-on-a-chip (SoC) such as SoC 100, for example.

### Example Aspects

Aspect 1: An apparatus for managing a clock in a design for test process for testing a processing core; comprising: a first clock gate coupled to one or more internal registers on a first clock gate path; at least one clone of the first clock gate coupled to at least one wrapper chain on a second clock gate path; and a first user-defined clock gate coupled to the first clock gate, the first user-defined clock gate being configured to gate a clock signal to the one or more internal registers based on a mode of the design for test process.
Aspect 2: The apparatus of Aspect 1, further comprising an on-chip clock controller coupled to the first user-defined clock gate.
Aspect 3: The apparatus of Aspect 1 or 2, in which the on-chip clock controller is coupled to the at least one clone of the first clock gate.
Aspect 4: The apparatus of any preceding Aspect, further comprising a test controller coupled to the first user-defined clock gate.
Aspect 5: The apparatus of any preceding Aspect, further comprising a second user-defined clock gate, coupled to the at least one wrapper chain.
Aspect 6: A method comprising: applying a clock signal to a circuit to test one or more cores in accordance with a design for test process, the circuit including at least a first clock gate path and a second clock gate path; and controlling one or more clock gates to disable at least one of the first clock gate path of the circuit or the second clock gate path based on a test mode of the design for test process.
Aspect 7: The method of Aspect 6, wherein the circuit includes at least one user-defined clock gate coupled to the first clock gate path and the second clock gate path, the first clock gate path having at least a first clock gate and one or more internal registers and the second clock gate path having at least one clock gate clone and one or more dedicated registers.
Aspect 8: The method of Aspect 6 or 7, wherein the test mode is an Intest mode and the method further comprises controlling the at least one user-defined clock gate to enable the clock signal for the first clock gate path and the second clock gate path.
Aspect 9: The method of any of Aspects 6-8, wherein the test mode is an Extest mode and the method further comprises controlling the at least one user-defined clock gate to disable the clock signal for the first clock gate path.
Aspect 10: The method of any of Aspects 6-9, wherein the test mode is the Extest mode and the method further comprises controlling the at least one user-defined clock gate to enable the clock signal for the second clock gate path.
Aspect 11: The method of any of Aspects 6-10, wherein the one or more cores are included in a system-on-a-chip (SoC).
Aspect 12: An apparatus comprising: means for applying a clock signal to a circuit to test one or more cores in accordance with a design for test process, the circuit including at least a first clock gate path and a second clock gate path; and means for controlling one or more clock gates to disable at least one of the first clock gate path of the circuit or the second clock gate path based on a test mode of the design for test process.
Aspect 13: The apparatus of Aspect 12, wherein the circuit includes at least one user-defined clock gate coupled to the first clock gate path and the second clock gate path, the first clock gate path having at least a first clock gate and one or more internal registers and the second clock gate path having at least one clock gate clone and one or more dedicated registers.
Aspect 14: The apparatus of Aspect 12 or 13, wherein the test mode is an Intest mode and the apparatus further comprises means for controlling the at least one user-defined clock gate to enable the clock signal for the first clock gate path and the second clock gate path.
Aspect 15: The apparatus of any of Aspects 12-14, wherein the test mode is an Extest mode and the apparatus further comprises means for controlling the at least one user-defined clock gate to disable the clock signal for the first clock gate path.
Aspect 16: The apparatus of any of Aspects 12-15, wherein the test mode is the Extest mode and the apparatus further comprises means for controlling the at least one user-defined clock gate to enable the clock signal for the second clock gate path.
Aspect 17: The apparatus of any of Aspects 12-16, wherein the one or more cores are included in a system-on-a-chip (SoC).

In some aspects, the applying means and/or controlling means may, for example, be the core OCC 312, the user-defined CG 308, or the user-defined CG wrapper 310 configured to perform the functions recited. In another configuration, the aforementioned means may be any module or any apparatus configured to perform the functions recited by the aforementioned means.

The various operations of methods described above may be performed by any suitable means capable of performing the corresponding functions. The means may include various hardware and/or software component(s) and/or module(s), including, but not limited to, a circuit, an application specific integrated circuit (ASIC), or processor. Generally, where there are operations illustrated in the figures, those operations may have corresponding counterpart means-plus-function components with similar numbering.

For a firmware and/or software implementation, the methodologies may be implemented with modules (e.g., procedures, functions, and so on) that perform the functions described. A machine-readable medium tangibly embodying instructions may be used in implementing the methodologies described. For example, software codes may be stored in a memory and executed by a processor unit. Memory may be implemented within the processor unit or external to the processor unit. As used, the term “memory” refers to types of long term, short term, volatile, nonvolatile, or other memory and is not limited to a particular type of memory or number of memories, or type of media upon which memory is stored.

If implemented in firmware and/or software, the functions may be stored as one or more instructions or code on a computer-readable medium. Examples include computer-readable media encoded with a data structure and computer-readable media encoded with a computer program. Computer-readable media includes physical computer storage media. A storage medium may be an available medium that can be accessed by a computer. By way of example, and not limitation, such computer-readable media can include random access memory (RAM), read-only memory (ROM), electrically erasable read-only memory (EEPROM), compact disc read-only memory (CD-ROM) or other optical disk storage, magnetic disk storage or other magnetic storage devices, or other medium that can be used to store desired program code in the form of instructions or data structures and that can be accessed by a computer. Disk and disc, as used, include compact disc (CD), laser disc, optical disc, digital versatile disc (DVD), floppy disk, and Blu-ray® disc, where disks usually reproduce data magnetically, while discs reproduce data optically with lasers. Combinations of the above should also be included within the scope of computer-readable media.

In addition to storage on computer-readable medium, instructions and/or data may be provided as signals on transmission media included in a communications apparatus. For example, a communications apparatus may include a transceiver having signals indicative of instructions and data. The instructions and data are configured to cause one or more processors to implement the functions outlined in the claims.

Although the present disclosure and its advantages have been described in detail, it should be understood that various changes, substitutions, and alterations can be made without departing from the technology of the disclosure as defined by the appended claims. For example, relational terms, such as “above” and “below” are used with respect to a substrate or electronic device. Of course, if the substrate or electronic device is inverted, above becomes below, and vice versa. Additionally, if oriented sideways, above, and below may refer to sides of a substrate or electronic device. Moreover, the scope of the present disclosure is not intended to be limited to the particular configurations of the process, machine, manufacture, composition of matter, means, methods, and steps described in the specification. As one of ordinary skill in the art will readily appreciate from the present disclosure, processes, machines, manufacture, compositions of matter, means, methods, or steps, presently existing or later to be developed that perform substantially the same function or achieve substantially the same result as the corresponding configurations described may be utilized according to the present disclosure. Accordingly, the appended claims are intended to include within their scope such processes, machines, manufacture, compositions of matter, means, methods, or steps.

Those of skill would further appreciate that the various illustrative logical blocks, modules, circuits, and algorithm steps described in connection with the present disclosure may be implemented as electronic hardware, computer software, or combinations of both. To clearly illustrate this interchangeability of hardware and software, various illustrative components, blocks, modules, circuits, and steps have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the disclosure may be implemented or performed with a general-purpose processor, a digital signal processor (DSP), an application-specific integrated circuit (ASIC), a field-programmable gate array (FPGA) or other programmable logic device, discrete gate or transistor logic, discrete hardware components, or any combination thereof designed to perform the functions described. A general-purpose processor may be a microprocessor, but, in the alternative, the processor may be any conventional processor, controller, microcontroller, or state machine. A processor may also be implemented as a combination of computing devices, e.g., a combination of a DSP and a microprocessor, multiple microprocessors, one or more microprocessors in conjunction with a DSP core, or any other such configuration.

The steps of a method or algorithm described in connection with the present disclosure may be embodied directly in hardware, in a software module executed by a processor, or in a combination of the two. A software module may reside in RAM, flash memory, ROM, erasable programmable read-only memory (EPROM), EEPROM, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a user terminal. In the alternative, the processor and the storage medium may reside as discrete components in a user terminal.

The previous description of the present disclosure is provided to enable any person skilled in the art to make or use the present disclosure. Various modifications to the disclosure will be readily apparent to those skilled in the art, and the generic principles defined may be applied to other variations without departing from the spirit or scope of the disclosure. Thus, the present disclosure is not intended to be limited to the examples and designs described, but is to be accorded the widest scope consistent with the principles and novel features disclosed.

What is claimed is:

1. An apparatus for managing a clock in a design for test process for testing a processing core, the apparatus comprising:
a first clock gate coupled to one or more internal registers on a first clock gate path;
at least one clone of the first clock gate coupled to at least one wrapper chain on a second clock gate path; and
a first user-defined clock gate coupled to the first clock gate, the first user-defined clock gate being configured to gate a clock signal to the one or more internal registers based on a mode of the design for test process.

2. The apparatus of claim 1, further comprising an on-chip clock controller coupled to the first user-defined clock gate.

3. The apparatus of claim 2, in which the on-chip clock controller is coupled to the at least one clone of the first clock gate.

4. The apparatus of claim 1, further comprising a test controller coupled to the first user-defined clock gate.

5. The apparatus of claim 1, further comprising a second user-defined clock gate, coupled to the at least one wrapper chain.

6. A method comprising:
applying a clock signal to a circuit to test one or more cores in accordance with a design for test process, the circuit including at least a first clock gate path and a second clock gate path; and
controlling one or more clock gates to disable at least one of the first clock gate path of the circuit or the second clock gate path based on a test mode of the design for test process.

7. The method of claim 6, wherein the circuit includes at least one user-defined clock gate coupled to the first clock gate path and the second clock gate path, the first clock gate path having at least a first clock gate and one or more internal registers and the second clock gate path having at least one clock gate clone and one or more dedicated registers.

8. The method of claim 7, wherein the test mode is an Intest mode and the method further comprises controlling the at least one user-defined clock gate to enable the clock signal for the first clock gate path and the second clock gate path.

9. The method of claim 7, wherein the test mode is an Extest mode and the method further comprises controlling the at least one user-defined clock gate to disable the clock signal for the first clock gate path.

10. The method of claim 9, wherein the test mode is the Extest mode and the method further comprises controlling the at least one user-defined clock gate to enable the clock signal for the second clock gate path.

11. The method of claim 6, wherein the one or more cores are included in a system on a chip (SoC).

12. An apparatus comprising:
means for applying a clock signal to a circuit to test one or more cores in accordance with a design for test process, the circuit including at least a first clock gate path and a second clock gate path; and
means for controlling one or more clock gates to disable at least one of the first clock gate path of the circuit or the second clock gate path based on a test mode of the design for test process.

13. The apparatus of claim 12, wherein the circuit includes at least one user-defined clock gate coupled to the first clock gate path and the second clock gate path, the first clock gate path having at least a first clock gate and one or more internal registers and the second clock gate path having at least one clock gate clone and one or more dedicated registers.

14. The apparatus of claim 13, wherein the test mode is an Intest mode and the apparatus further comprises means for controlling the at least one user-defined clock gate to enable the clock signal for the first clock gate path and the second clock gate path.

15. The apparatus of claim 13, wherein the test mode is an Extest mode and the apparatus further comprises means for controlling the at least one user-defined clock gate to disable the clock signal for the first clock gate path.

16. The apparatus of claim 15, wherein the test mode is the Extest mode and the apparatus further comprises means for controlling the at least one user-defined clock gate to enable the clock signal for the second clock gate path.

17. The apparatus of claim 12, wherein the one or more cores are included in a system on a chip (SoC).
